(19) United States
(12) Patent Application Publication
(10) Pub. No.: US 2006/0084266 A1
(43) Pub. Date: Apr. 20, 2006

(54) Film formation method

(75) Inventors: Masaki Narushima, Nirasaki-shi (JP); Koumei Matsuzawa, Uodu-shi (JP); Hiroshi Sato, Nirasaki-shi (JP); Takayuki Komiya, Nirasaki-shi (JP); Eiichi Kondoh, Kai-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignees: TOKYO ELECTRON LIMITED, Minato-ku (JP); EIICHI KONDOH, Kai-Shi (JP)

(21) Appl. No.: 11/252,795

(22) Filed: Oct. 19, 2005

(30) Foreign Application Priority Data
Oct. 19, 2004 (JP) 2004-304536

(51) Int. Cl. H01L 21/44

(52) U.S. Cl. 438/674; 438/687; 438/681

(57) ABSTRACT

A film formation method of forming a film on a fine-pattern by supplying a processing medium that is in the supercritical state in which a precursor is dissolved on a target substrate is disclosed. The film formation method includes a first process of supplying the processing medium on the target substrate, the temperature of which is set at a first temperature that is lower than a film formation minimum temperature that is the lowest temperature at which film formation takes place, and a second process of forming the film on the target substrate by raising the temperature of the target substrate from the first temperature to a second temperature that is higher than the film formation minimum temperature.

### BACKGROUND OF THE INVENTION

1. Field of the Invention

The present invention relates to a film formation method using a medium in a supercritical state.

2. Description of the Related Art

In recent years and continuing, semiconductors devices are required to offer high performance and high integration, hence requirements for miniaturization are remarkable, and a wiring rule of 0.1 μm or less is in use. Further, as for wiring material, copper (Cu) having a low resistance value is used such that propagation delay due to wiring will be reduced.

Accordingly, the combination of Cu film formation technology and miniaturized wiring technology is an important key element of multilayer-wiring technology.

As for the Cu film formation method, a spattering method, a CVD method, a plating method, etc., are generally in practice. However, according to the methods, since there is a limit in coverage, it is very difficult to efficiently form the Cu film on a fine-pattern having a high aspect ratio where miniaturized wiring of 0.1 μm or less is required.

Then, as the method of efficiently forming the Cu film on the fine-pattern, a Cu film formation method using a medium in the supercritical state is proposed.

If a material in the supercritical state is used as the medium for dissolving a precursor compound (precursor) for film formation,

since the density and the solubility of the material in the supercritical state are similar to those of a liquid,

the solubility of the precursor can be maintained high compared with a gaseous medium, and

by using a diffusion coefficient near gas, the precursor can be introduced to a process target more efficiently than with a liquid medium. Therefore, according to the film formation using the processing medium, which is a medium in the supercritical state in which a precursor is dissolved, the film formation can be efficiently performed with a satisfactory coverage of the fine-pattern.

For example, a method of forming a Cu film is proposed, e.g., by Non-Patent Reference 1, wherein a precursor for Cu film formation is dissolved in CO₂ in the supercritical state for obtaining the processing medium.

In this case, since the solubility of the Cu film formation precursor is high and its viscosity is low, diffusion is high; for this reason, Cu film formation is attained with a satisfactory coverage on the fine-pattern with a high aspect ratio. Here, the Cu film formation precursor is a precursor compound containing Cu dissolved in the medium CO₂ in the supercritical, state.

[Non-Patent Reference 1] “Deposition of Conformal Copper and Nickel Films from Supercritical Carbon Dioxide”, SCIENCE vol. 294 2001 Oct. 5.

[Description of the Invention]

[Problem(s) to be Solved by the Invention]

However, even if the medium in the supercritical state is used as described above, with miniaturization of the circuit pattern, when the openings in patterns are further miniaturized, and the aspect ration becomes still greater, insufficient coverage of the pattern and insufficient filling pose problems.

### SUMMARY OF THE INVENTION

In view of the above, the present invention provides a film formation method that substantially obviates one or more of the problems caused by the limitations and disadvantages of the related art.

A preferred embodiment of the present invention provides a film formation method of forming a film on a fine-pattern using a medium in the supercritical state, providing improved coverage of and filling properties for to the fine-pattern that are finer than conventional, and enabling a film to be formed on a further fine-pattern.

Features of the present invention are set forth in the description that follows, and in part become apparent from the description and the accompanying drawings, or may be learned by practice of the invention according to the teachings provided in the description. Problem solutions provided by the present invention are realized and attained by a film formation method particularly pointed out in the specification in such full, clear, concise, and exact terms as to enable a person having ordinary skill in the art to practice the invention.

To achieve these solutions and in accordance with the purpose of the invention, as embodied and broadly described herein, the invention provides the film formation method as follows.

[Means for Solving the Problem]

An aspect (first aspect) of the present invention offers a film formation method wherein a film is formed on a target substrate by supplying a processing medium that is a medium in the supercritical state in which a precursor is dissolved, the film formation method including,

a first process of heating the target substrate to a first temperature that is the lowest temperature at which a film can be formed or lower, and supplying the processing medium to the target substrate, and

a second process of forming the film on the target substrate by raising the temperature of the target substrate from the first temperature to a second temperature that is higher than the lowest temperature at which the film can be formed.

According to another aspect of the present invention, the difference between the first temperature and the second temperature is between 50 and 300° C.

According to another aspect of the present invention, the difference between the first temperature and the lowest temperature at which the film can be formed is between 10 and 100° C.

According to another aspect of the present invention, the precursor is one of Cu(hfac)₂, Cu(acac)₂, Cu(dpm)₂, Cu(dibm)₂, Cu(ibpm)₂, Cu(hfac)TMVS, and Cu(hfac)COD,

According to another aspect of the present invention, the first temperature is between 100 and 250° C.

According to another aspect of the present invention, the second temperature is between 200 and 400° C.

According to another aspect of the present invention, the film formation is carried out so that a pattern formed on the target substrate may be buried (filled).

According to another aspect of the present invention, the pattern is formed on an insulation layer formed on the target substrate.

According to another aspect of the present invention, a reducing agent of the precursor is added to the processing medium.

According to another aspect of the present invention, the medium in the supercritical state is CO₂.

According to another aspect of the present invention, the first process and the second process are carried out in a processing container in which a holding stand for holding the target substrate is provided, the processing medium is provided to the inside of the processing container, and the temperature of the target substrate is raised by a heater provided in the holding stand.

According to another aspect of the present invention, inert gas is provided into the processing container when the target substrate is carried into or taken out from the processing container.

According to another aspect of the present invention, the processing container is connected to a substrate conveyance chamber that can connect two or more processing containers.

According to another aspect of the present invention, the substrate conveyance chamber is connected to the processing container and one or more processing containers.

According to another aspect of the present invention, a shielding plate is provided to the processing container such that the holding stand may be covered.

According to another aspect of the present invention, the medium in the supercritical state is provided in a space between the shielding plate and the holding stand.

According to another aspect of the present invention, a film formation prevention plate is provided in the processing container so that a periphery section of the target substrate held by the holding stand may be covered.

According to another aspect of the present invention, the film formation prevention plate is capable of moving toward and departing from the target substrate.

According to another aspect of the present invention, the film formation prevention plate has a projecting section that covers the periphery section of the target substrate.

According to another aspect of the present invention, the medium in the supercritical state is provided into a space between the film formation prevention plate and the holding stand.

Further, an embodiment of the present invention provides a storage unit for storing a computer-executable program for a computer to perform the film formation method of the present invention.

[Effect of the Invention]

According to the film formation method of an embodiment of the present invention using the medium in the supercritical state, a film can be formed on a fine-pattern with improved coverage and filling properties as compared with conventional practices. Further, the film formation method of the embodiments of the present invention can be applied to a further fine-pattern.

### BRIEF DESCRIPTION OF THE DRAWINGS

FIG. 1 is a flowchart showing a film formation method according to Embodiment 1 of the present invention;

FIG. 2 is a schematic drawing showing an example of a film formation apparatus that can carry out Embodiment 1 of the present invention;

FIGS. 3A and 3B are cross-sectional views showing details of a processing container of the film formation apparatus shown by FIG. 2;

FIGS. 4A and 4B are plan views showing examples of a film formation system using the processing container as shown by FIGS. 3A and 3B;

FIGS. 5A and 5B are cross-sectional views of a semiconductor device that is manufactured using the film formation method according to Embodiment 1;

FIGS. 6A and 6B are cross-sectional views of the semiconductor device that is manufactured using the film formation method according to Embodiment 1;

FIGS. 7A, 7B, and 7C are cross-sectional views showing modifications of the processing container shown in FIGS. 3A and 3B;

FIG. 8A is a cross-sectional view showing a modification of the processing container shown in FIGS. 3A and 3B; and

FIG. 8B is a cross-sectional view showing an enlargement of a part of FIG. 8A.

### DESCRIPTION OF THE PREFERRED EMBODIMENTS

In the following, embodiments of the present invention are described with reference to the accompanying drawings.

### Embodiment 1

A film formation method according to Embodiment 1 of the present invention forms a Cu film that fills a miniature pattern that is formed on a target substrate, the Cu film being, e.g., for wiring of a semiconductor device.

According to Embodiment 1, the Cu film is formed on the target substrate by providing a processing medium on the target substrate. Here, the processing medium is a medium in which a precursor is dissolved, the medium being in the supercritical state. The precursor dissolved in the medium in the supercritical state has a high solubility, and a low viscosity; for this reason, it has a high diffusion rate. Accordingly, the Cu film can be formed on a highly fine-pattern complying with a wiring rule of, for example, 0.1 μm or less with sufficient coverage, such that detailed circuit patterns such as via wiring and trench wiring can be formed.

Even if the medium in the supercritical state is used in the film formation, there is a limit in improvement of the coverage and filling properties. Especially, when the film is to be formed on a pattern that is further miniaturized or a pattern having a higher aspect ratio, coverage can be insufficient, and a void (wiring gap) can be generated in a wiring section, resulting in poor wiring.

The coverage and filling properties tend to be degraded when the pattern is miniaturized, which is considered to occur for the following reasons.

When the processing medium that is the medium in the supercritical state in which the precursor is dissolved is supplied to the target substrate, pyrolysis of the precursor quickly advances near the opening of the fine-pattern formed on the target substrate, the film formation speed near the opening becomes high, and the precursor is prevented from sufficiently spreading to bottom and sidewall sections of the fine-pattern; thereby the coverage and filling properties are degraded. Further, since the concentration of a medium in the supercritical state generally tends to be sharply changed by temperature, the processing medium that is heated near the target substrate tends to move by convection in a direction departing from the target substrate, i.e., upward, which is considered to prevent the processing medium from getting into a hole (recess) of the fine-pattern.

As described above, it is considered that if the temperature of the target substrate is higher than a certain temperature when the processing medium is supplied on the fine-pattern of the target substrate, the fulling and coverage properties at the time of film formation will be degraded.

In view of this, according to Embodiment 1, the film formation method of forming a film by supplying a processing medium on a target substrate, the processing medium being a medium in the supercritical state in which a precursor is dissolved includes

a first process of setting the target substrate at a first temperature that is less than a film formation minimum temperature, which film formation minimum temperature is the lowest temperature at which film formation can take place, and supplying the processing medium on the target substrate, and

a second process of forming a film on the target substrate by raising the temperature of the target substrate from the first temperature to a second temperature that is greater than the film formation minimum temperature.

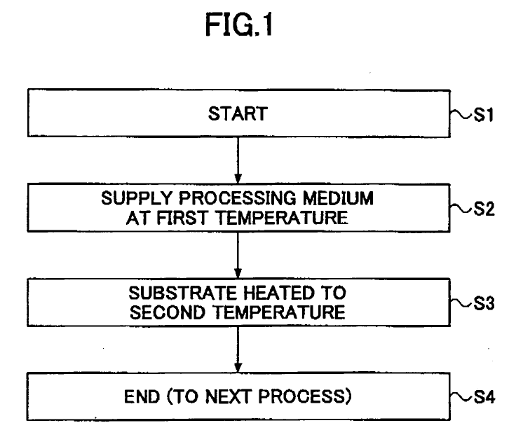

The outline of the film formation method according to Embodiment 1 is shown in FIG. 1.

With reference to FIG. 1, the process of the film formation method according to Embodiment 1 starts at Step 1 (indicated as S1 in FIG. 1, the same applying to other Steps). Then the processing medium consisting of the medium in the supercritical state in which the precursor is dissolved is supplied on the target substrate at Step 2. Since the target substrate is set at the first temperature (that is, less than the film formation minimum temperature) at this step, the processing medium permeates and spreads well into the inside of a hole of the pattern formed on the target substrate.

Next, at Step 3, the temperature of the target substrate is raised to the second temperature, which is higher than the film formation minimum temperature. Then, the precursor is decomposed, and a film is formed inside such as on the bottom or the sidewall section of the hole of the pattern on the target substrate such that the film is filled in the pattern. The film formation is completed at Step 4.

As described above, according to Embodiment 1, when the processing medium in the supercritical state in which precursor is dissolved is supplied on the target substrate, a film is not substantially formed on the target substrate (fine-pattern formed on the target substrate), the processing medium, therefore, the precursor, sufficiently spreads into the hole of the fine-pattern. In other words, since the target substrate is set at the first temperature which is less than the film formation minimum temperature that is the lowest temperature for the film to be formed, reaction of the precursor that may otherwise take place by being heated through the heated target substrate is prevented from occurring, and film formation is prevented from taking place on the target substrate. In this way, the hole of the fine-pattern can be filled with the precursor that has not undergone reaction.

After the processing medium (therefore, the precursor) spreads inside the hole, the temperature of the target substrate is raised from the first temperature to the second temperature that is higher than the film formation minimum temperature, and the film is formed filling the hole.

As described, according to Embodiment 1, the filling and coverage properties concerning the fine-pattern are improved in comparison with the conventional film formation method. Further, generating of a void and the like are prevented from occurring. For this reason, the film formation method of the present embodiment is capable of forming miniaturized wiring that can be used by a semiconductor device and the like.

In addition, while the first temperature at Step 2 is desired to be below the film formation minimum temperature that is the lowest temperature at which film formation takes place, if the first temperature is set too low, it takes a long time to raise the temperature from the first temperature to a temperature at which film formation takes place, e.g., the second temperature, resulting in inefficiency of film formation.

Then, in order to make the process efficient, the first temperature is desired to be high. Accordingly, it is desirable that the difference between the first temperature and the second temperature, (i.e., the difference between the temperatures of the target substrate at Step 2 and Step 3) be 300° C. or less. Further, it is desirable that the difference between the first temperature and the film formation minimum temperature be 100° C. or less.

Nevertheless, if the difference between the first temperature and the second temperature is made too small, or if the difference between the first temperature and the film formation minimum temperature is made too small, film formation may be carried out on the pattern at the first temperature, and the filling and coverage properties may be degraded. Further, the film formation minimum temperature may not be constant, and the temperature may not be accurately measured; accordingly, it is desired to provide predetermined differences between the first temperature and the second temperature, and between the first temperature and the film formation minimum temperature.

For this reason, it is desirable that the difference between the first temperature and the second temperature, i.e., the difference between the temperatures of the target substrate at Step 2 and Step 3 be 50° C. or greater, and it is desirable that the difference between the first temperature and the film formation minimum temperature be 10° C. or greater.

For example, when a Cu film is to be formed on the target substrate, and the precursor to be dissolved in the medium in the supercritical state is Cu(hfac)₂ (hfac being hexafluoroacetylacetonato), the film formation minimum temperature is approximately in a range between 150° C. and 250° C.

In this case, in order to obtain satisfactory filling and coverage properties, and high processing efficiency of film formation, the first temperature is desired to be between 100° C. and 250° C., and the second temperature is desired to be between 200° C. and 400° C.

The film formation method of Embodiment 1 is applicable to formation of a film of various materials on various patterns. For example, it is possible to form a metal film, for example, a Cu film, being filled on a pattern formed on, e.g., an insulation layer consisting of a silicon oxide film.

Here, the insulation layer is not limited to a silicon oxide film (SiO₂ film); but other insulator layers may be used, such as a fluorine added silicon oxide film (SiOF film), a SiC film, a SiCO(H) film, and porosity films thereof.

Further, when forming a Cu film, for example, a metal complex adduct may serve as the precursor. Here, the metal complex adduct is a metal complex to which a molecule is added, the molecule containing at least one of a group of carbohydrates and organic silane having a bond of an electron donative nature. Here, the metal complex may be of a divalent copper ion to which two beta-diketonato ligands are arranged, and of a mono-valent copper ion to which one beta-diketonato ligand is arranged.

Further, the precursor can be an organic metal complex and an organic metal complex adduct that contain at least one of the divalent copper ion and the mono-valent copper ion. Further, the precursor can be an organic mixture that contains at least one of the organic metal complexes and the organic metal complex adduct.

The precursor when forming a Cu film can be, e.g., Cu(acac)₂, Cu(dpm)₂, Cu(dibm)₂, Cu(ibpm)₂, Cu(hfac)TMVS, and Cu(hfac)COD; these materials provide the same result as the case where Cu(hfac)₂ is used.

Here, dpm stands for dipivaloylmethanato, dibm stands for diisobutyrylmethanato, ibpm stands for isobutyrylpivaloylmethanato, acac stands for acetylacetonato, TMVS stands for trimethylvinylsilan, and COD stands for 1.5-cyclooctadiene.

Further, the film to be formed on the target substrate is not limited to the Cu film, but other metal films can be formed, e.g., tantalum, tantalum nitride, titanium nitride, tungsten, tungsten nitride, and metal compound films. These metal films and metal compound films serve as a Cu diffusion prevention film when forming Cu wiring on a fine-pattern. In this way, the Cu diffusion prevention film can be efficiently formed on the fine-pattern, and the same effect is obtained as in Embodiment 1 wherein the Cu film is formed.

Further, the medium in the supercritical state is not limited to CO₂, but other materials may be used, e.g., NH₃. When NH₃ is used, a metal nitride film is formed.

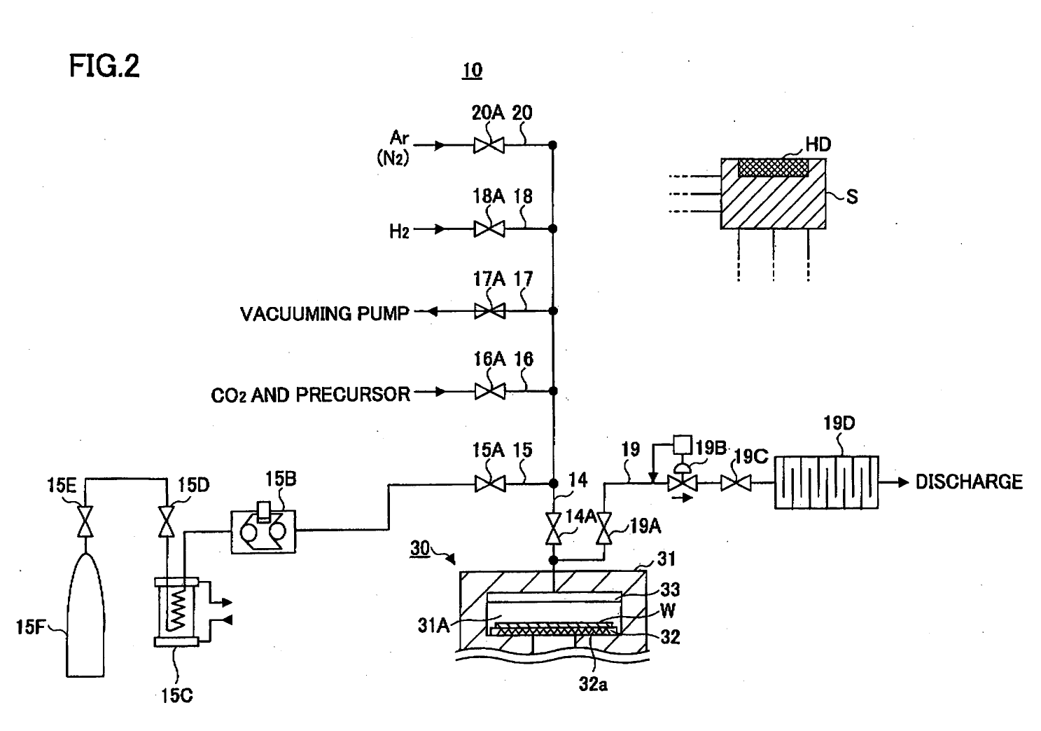

Next, a film formation apparatus 10 for processing the film formation method according to Embodiment 1 is described. FIG. 2 shows the outline structure of an example of the film formation apparatus 10.

With reference to FIG. 2, the film formation apparatus 10 includes a processing container 30 that includes an outer wall structure 31, a processing space 31A that may be shaped like, e.g., a cylinder, the processing space 31A being enclosed by the outer wall structure 31, and a holding stand 32 for holding a target substrate W in the processing space 31A. A heater 32a is arranged in the holding stand 32 so that the target substrate W laid on the holding stand 32 may be heated.

Further, a supply section 33 is formed on the side that counters the holding stand 32 of the processing space 31A, the supply section 33 having a so-called shower head structure where two or more supply holes are formed for supplying the medium in the supercritical state and the processing medium (the medium in the supercritical state in which the precursor is dissolved) to the processing space 31A. A line 14 to which a valve 14A is arranged is connected to the supply section 33. By this structure, the medium in the supercritical state and the processing medium (the medium in the supercritical state in which the precursor is dissolved) are supplied through the line 14, and from the supply section 33 to the processing space 31A. When the target substrate is carried into or taken out from the processing container 30, a gate valve (not illustrated) is opened, and the processing container 30 is opened. Further, the holding stand 32 is capable of moving up and down by a mechanism (not illustrated). The gate valve and the mechanism are described in detail below.

Further, the following lines, each having a valve, are connected to the supply line 14; namely,

a line 15 to which a valve 15A is attached for supplying the medium in the supercritical state to the supply line 14,

a line 16 to which a valve 16A is attached for supplying the precursor to the line 14,

a line 17 to which a valve 17A and a vacuum pump are attached for evacuating the supply line 14 and the processing space 31A as required,

a line 18 to which a valve 18A is attached for supplying gas required of film formation, such as a reducing agent, to the line 14, and

a line 20 to which a valve 20A is attached for supplying inert gas, such as Ar, to the line 14.

On the line 15, a tank 15F containing, e.g., CO₂ that is a medium serving as the base of the medium in the supercritical state is connected through a pressurization pump 15B, a cooler 15C, a valve 15D, and a valve 15E. The CO₂ is supplied from the tank 15F, cooled by the cooler 15C, compressed by the pressurization pump 15B to a predetermined pressure and predetermined temperature such that it becomes the medium in the supercritical state, and provided to the processing space 31A. In the case of CO₂, for example, the critical point (point at which the supercritical state is obtained) is the temperature of 31.0° C., and pressure of 7.38 MPa.

Further, through the line 16, the precursor such as Cu(hfac)₂ is supplied, and through the line 18, a reducing agent such as H₂ gas is supplied, both being supplied to the processing space 31A.

Furthermore, a discharge line 19 is connected to the processing container 30, the discharge line 19 being for discharging the processing medium, the medium in the supercritical state, etc., supplied to the processing space 31A, and being connected to a valve 19A, a valve 19C, and a trap 19D. The precursor dissolved in the processing medium is captured by the trap 19D and discharged outside the processing space 31A. The discharge line 19 is further connected to a pressure control valve 19B for controlling the pressure of the discharge line 19 at a desired level when the processing medium, the medium in the supercritical state, etc., supplied to the processing space 31A are discharged.

Further, the film formation apparatus 10 includes a control unit S that further includes a storage unit HD that is a hard disk, and a CPU (not illustrated). The control unit S causes the CPU to run the film formation apparatus 10 according to a program stored in the storage unit HD. For example, based on the program, the control unit 10, e.g., causes the medium in the supercritical state to be supplied to the processing container 30, and causes gas in the processing container 30 to be discharged by operation of the valves, etc.; controls the heater for temperature control of the target substrate; and causes the film formation apparatus 10 to perform operations in connection with film formation processing. Here, the program of the film formation stored by the storage unit HD is sometimes called a recipe. Operations of the film formation apparatus 10 for film formation as described above are performed by the control unit S according to the program (recipe) stored by the storage unit HD.

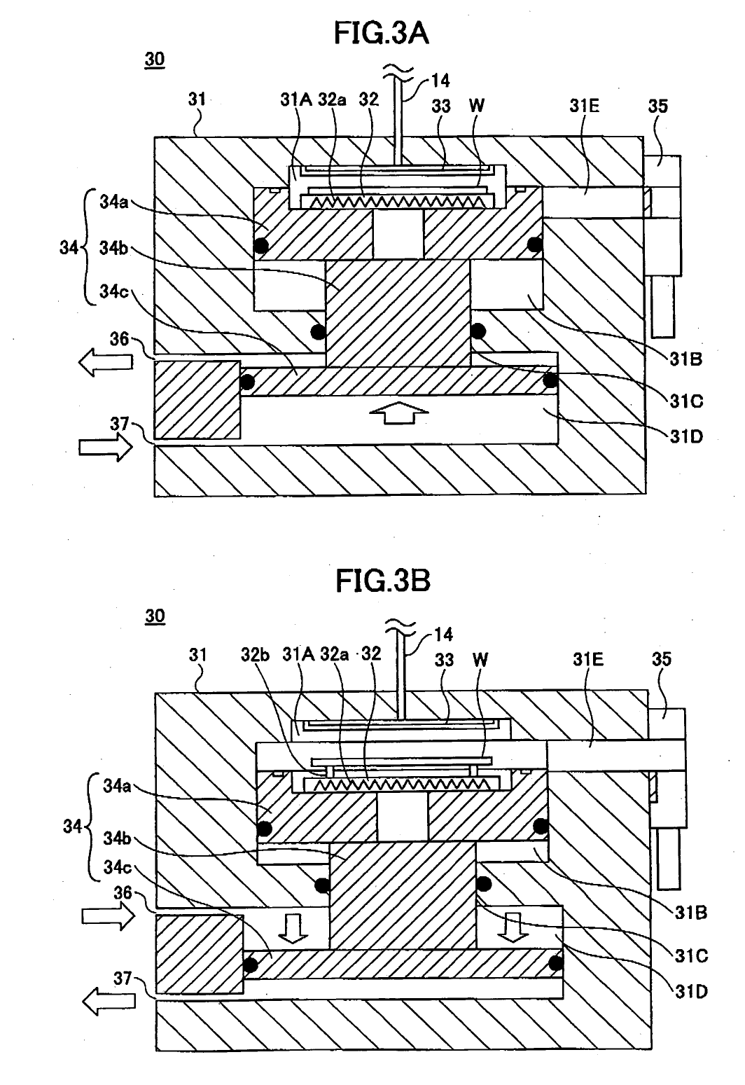

Next, the processing container 30 is described in detail with reference to FIG. 3A and FIG. 3B, which are cross-sectional views showing the details of the processing container 30 shown in FIG. 2. Here, the same reference marks are given to the same portions as described above, and the descriptions thereof are not repeated.

First, with reference to FIG. 3A, the processing container 30 includes the processing space 31A structured by the outer wall structure 31. In the processing space 31A, the holding stand 32 is supported by a holding stand support section 34, and the holding stand support section 34 consists of an upper structure 34a, a central structure 34b, and a substructure 34c. The outer wall structure 31 further includes

an upper space 31B that is open for free passage to the processing space 31A, the upper space 31B being shaped like a cylinder, for example,

a central space 31C,

a lower space 31D that is open for free passage to the processing space 31A through the upper space 31B and the central space 31C, the lower space 31D being shaped like a cylinder, for example. The upper space 31B and the processing space 31A are isolated by the holding stand 32 and the upper structure 34a.

The upper structure 34a is made movable up and down, and is shaped like a cylinder. The circumference of the upper structure 34a touches the inner surface of the wall of the upper space 31B, providing air tightness of the processing space 31A by, e.g., a seal material installed on the contact surface.

Similarly, the substructure 34c, which is shaped like a cylinder is formed so that the inner surface of the wall of the lower space 31D may be touched in the circumference, where air tightness of the lower space 31D isolated by the substructure 34c is held by, for example, a seal material installed on the contact surface, and the substructure 34c is made movable up and down. Further, the central structure 34b, which is shaped like a cylinder, is formed so that the inner surface of the wall of the central space 31C may be touched in the circumference, where air tightness between the upper space 31B and the lower space 31D is held by, for example, a seal material installed on the contact surface, and the central structure 34b is made movable up and down.

Further, an inlet/outlet 36 and an inlet/outlet 37 are formed at an upper section and at a lower section, respectively, of the lower space 31D such that a gas, e.g., air and N₂, can be provided to and discharged from the lower space 31D, the gas driving the holding stand support 34.

Further, the outer wall structure 31 further includes a target substrate path 31E that provides a free passage to the processing space 31A through the upper space 31B, and a gate valve 35 that opens and closes the free passage arranged at the end of the target substrate path 31E, i.e., on the outside of the outer wall structure 31. The gate valve 35 is wide open when carrying in a target substrate to the processing space 31A, and when taking out the target substrate from the processing space 31A. When film formation processing is performed on the target substrate, the gate valve 35 is closed.

FIG. 3A represents a state where the gate valve 35 is closed, and film formation processing is being performed.

In this case, gas (such as air and N₂), or a liquid, for example, is introduced from the inlet/outlet 37, and discharged from the inlet/outlet 36. Force is generated in a direction that pushes up the holding stand support section 34. Then, the processing space 31A is formed by the outer wall structure 31, the holding stand 32, and the holding stand support section 34. Then, a processing medium is supplied to the processing space 31A from the supply section 33, and film formation processing is performed.

FIG. 3B shows the processing container 30 when the target substrate is carried into and taken out from the processing container 30.

With reference to FIG. 3B, for example, gas is introduced through the inlet/outlet 36 and discharged from the inlet/outlet 37. Force is generated in a direction that the holding stand support section 34 and the holding stand 32 are lowered. Further, the gate valve 35 is opened, and the space where the target substrate is held is open to the exterior of the processing container 30 through the target substrate path 31E and the gate valve 35. Further, the target substrate is raised by two or more pins 32b arranged on the holding stand 32, and the target substrate is conveyed by, e.g., a conveyance arm described below.

Further, it is desirable to introduce inert gas, such as Ar, into the processing container 30 from the supply section 33 in this case. This is for preventing a film, such as a Cu film, from being formed on the target substrate due to reaction, such as oxidation reaction, by oxygen that may be around, especially when the temperature of the target substrate is high. With the film formation apparatus 10 of the present Embodiment, when opening the processing container for carrying in or taking out the target substrate, Ar gas is introduced through the supply section 33 through the line 14 so that the film formed on the target substrate is prevented from degrading. Here, the inert gas is not limited to Ar, but other gases can be used, for example, N₂ and helium. In addition, in order to prevent the degradation of the film after formation, it is also effective to reduce the pressure inside of the processing container 30 by evacuating the inside of the processing container 30 through the line 17.

Further, the processing container 31 constituted in this way can be connected to a substrate conveyance chamber that has a conveyance arm for conveying a target substrate; then, the efficiency of substrate conveyance and the efficiency of film formation processing are improved.

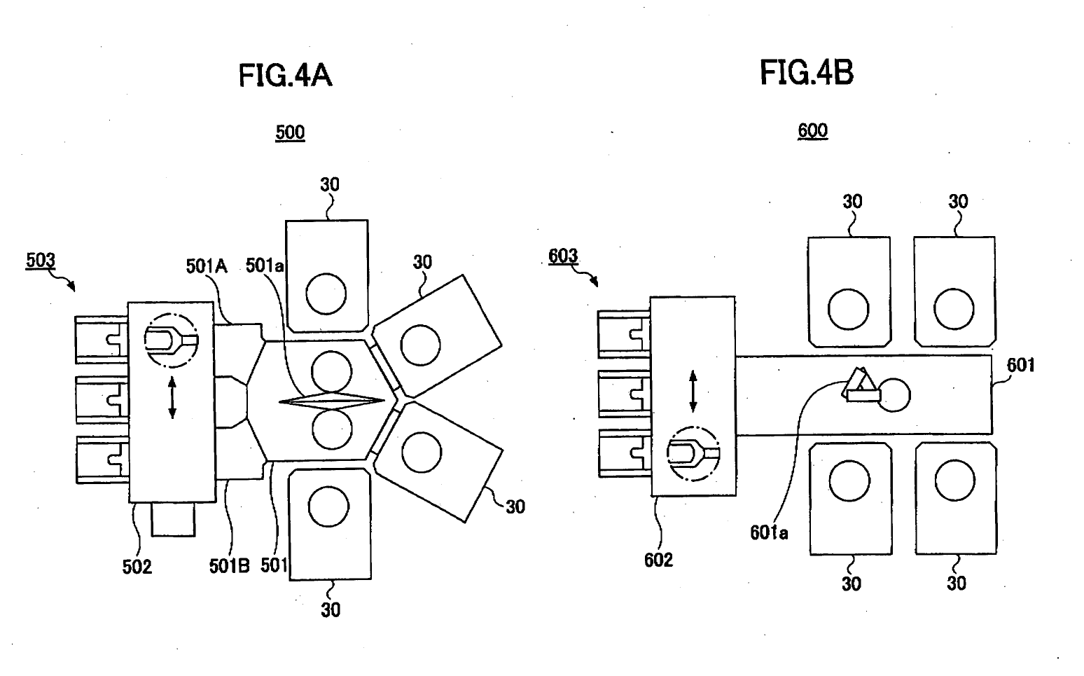

FIGS. 4A and 4B show film formation systems 500 and 600, respectively, that include the processing container 30 as shown in FIGS. 3A and 3B connected to the substrate conveyance chamber. FIG. 3A shows the film formation system 500 wherein the substrate conveyance chamber is in a reduced pressure state. FIG. 3B shows the film formation system 600 wherein the substrate processing chamber is at approximately the normal atmospheric pressure. Here, the same reference marks are is given to the same portions that are described above, and the explanations thereof are not repeated.

First, with reference to FIG. 4A, the film formation system 500 includes two or more processing containers 30 that are connected to a substrate conveyance chamber 501, the pressure inside of which can be reduced by an exhausting facility (illustration omitted), the substrate conveyance chamber 501 including a conveyance arm 501a for conveying a target substrate, and being shaped like, e.g., a hexagon.

Further, load lock chambers 501A and 501B are connected to the substrate conveyance chamber 501, and the load lock chambers 501A and 501B are connected to a substrate station 503 that has a substrate conveyance section 502.

The film formation system 500 is configured such that the target substrate laid on the substrate station 503 is conveyed by the substrate conveyance section 502 to one of the load lock chambers 501A and 501B, which is in the reduced pressure state; further, the target substrate is conveyed by the conveyance arm 501a into the processing container 30 through the substrate conveyance chamber 501 from the corresponding load lock chamber. Further, when film formation processing is finished, the target substrate is conveyed by the conveyance arm 501a from the processing container 30 through the substrate conveyance chamber 501 to the load lock chamber, and is further conveyed from the load lock chamber to the substrate station 503.

On the other hand, with reference to FIG. 4B, the film formation system 600 includes two or more processing containers 30 that are connected to a substrate conveyance chamber 601 that has a conveyance arm 601a for conveying the target substrate. Furthermore, a substrate station 603 that has a substrate conveyance section 602 is connected to the substrate conveyance chamber 601.

The film formation system 600 is configured such that the target substrate laid on the substrate station 603 is conveyed by the conveyance arm 601a in the processing container 30 through the substrate conveyance chamber 601 through the substrate conveyance section 602. Further, when film formation processing is ended, the target substrate is conveyed by the conveyance arm 601a through the substrate conveyance chamber 601 to the substrate station from the processing container 30. Since the substrate conveyance chamber is at approximately the normal atmospheric pressure, an evacuation facility and a load lock chamber are not required.

Next, an example is described wherein a Cu film is formed on a fine-pattern formed on the target substrate, the example employing the film formation method shown in FIG. 1, and the film formation apparatus 10 shown in FIG. 2, which includes the processing container as shown in FIG. 3A and FIG. 3B.

The film formation process is started at Step 1 shown in FIG. 1, the gate valve 15 is opened wide, the target substrate is carried into the processing space 31A, and the target substrate is laid on the holding stand 32. Next, after reducing the atmospheric pressure of (evacuating) the processing space 31A using the line 17, the target substrate is heated by the heater arranged in the holding stand 32, and the temperature of the target substrate is set at 150° C.

Next, through the line 15, CO₂ is introduced into the processing space 31A, and the pressure of the processing space 31A is raised. Alternatively, CO₂ beforehand made into the supercritical state may be introduced. Alternatively, CO₂ as the medium in the supercritical state may be produced in the processing space 31A by continuously supplying liquid CO₂ to the processing space 31A and by raising the temperature of CO2, in addition to or instead of raising the pressure of the supplied CO₂. Further, at the same time of or before increasing the pressure of the processing space 31A, H₂ is introduced through the line 18 to the processing space 31A such that the H₂ is mixed with the processing medium, and the mixed processing medium is used for processing. Here, the pressure of the processing space 31A is 15 MPa, for example.

Next, the medium in the supercritical state in which a precursor, e.g. Cu(hfac)₂ is dissolved, i.e., the processing medium, is supplied through the line 16 to the target substrate on the holding stand of the processing space 31A. In this case, since the temperature of the target substrate is less than the film formation minimum temperature, substantial film formation does not take place, but the processing medium, i.e., the precursor permeates the hole of the fine-pattern. In this case, since the diffusion rate of the medium in the supercritical state in which the precursor is dissolved is high, the precursor can efficiently spread even near the bottom of the hole of the fine-pattern. Further, since the temperature of the target substrate is less than the film formation minimum temperature, the precursor is not consumed near the opening in the fine-pattern, and since there is little influence of convection of the medium in the supercritical state, the precursor efficiently permeates into the fine-pattern.

Next, at Step 3, by heating the target substrate, e.g., at 300° C. by the heater 32a, the precursor on the target substrate is pyrolyzed, and the Cu film is formed so that the fine-pattern form on the target substrate may be filled.

Accordingly, the Cu film is formed on the fine-pattern having a line breadth of, e.g., 0.1 μm or less formed on the insulator layer at a high film formation speed with high filling and coverage properties.

Next, after the film formation for a predetermined time, supply of the processing medium is stopped, the valves 19A and 19C are opened wide, and the processing medium in the processing space 31A is discharged through the discharge line 19. In this case, the pressure of the medium to be discharged is controlled by the pressure adjustment valve 19B such that the pressure does not become too high, but becomes a predetermined pressure. In this case, CO₂ is supplied through the line 15 to the processing space 31A such that the processing space 31A is purged as required.

Next, after the purge is completed, the processing space 31A is returned to atmospheric pressure, and the film formation is completed.

### Embodiment 2

Next, an example of forming a semiconductor device using the method described in Embodiment 1 is described.

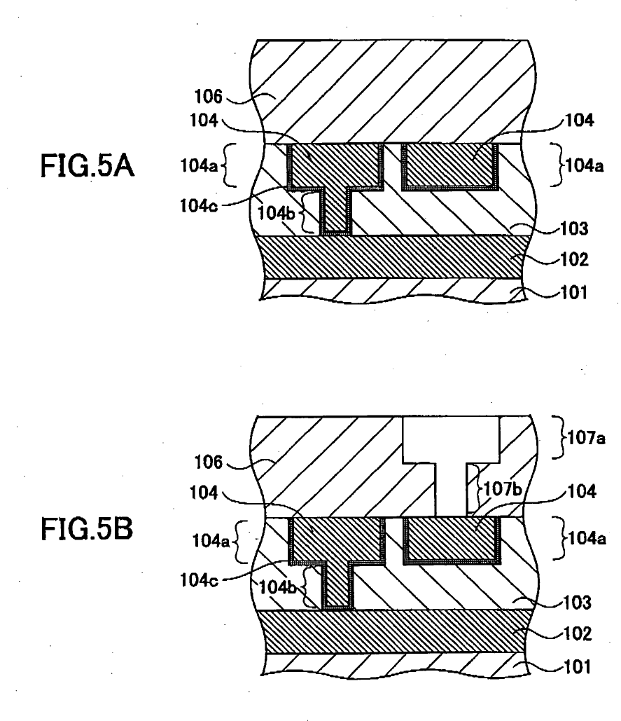

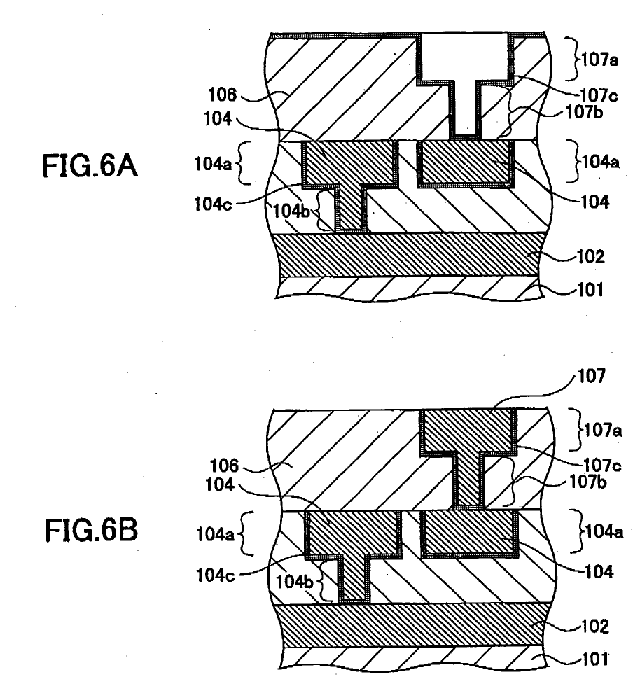

FIGS. 5A, 5B, 6A, and 6B show a process flow of the example of forming the semiconductor device using the film formation method described in Embodiment 1.

First, with reference to FIG. 5A, an insulator layer 101 such as a silicon oxide film 101 is formed so that elements (not shown), e.g., MOS transistors, that are formed on a semiconductor substrate (the target substrate) consisting of silicon may be covered. Then the target substrate is electrically connected to the elements. For example, a wiring layer 102 consisting of Cu and a wiring layer (not shown) consisting of W (tungsten) electrically connected to the wiring layer 102 are formed.

Further, a first insulation layer 103 is formed on the silicon oxide film 101 so that the wiring layer 102 may be covered. A ditch 104a and a through hole 104b are formed in the first insulation layer 103. A wiring section 104 made of Cu that consists of trench wiring and via wiring is formed in the ditch 104a and the through hole 104b, the wiring section 104 being electrically connected to the wiring layer 102.

Further, a Cu diffusion prevention film 104c is formed between the first insulation layer 103 and the wiring section 104. The Cu diffusion prevention film 104c prevents Cu of the wiring section 104 from diffusing to the first insulation layer 103. Further, a second insulation layer 106 is formed so that the upper surface of the wiring section 104 and the first insulation layer 103 may be covered. In Embodiment 2, the film formation method of the present invention is applied to the second insulation layer 106 for forming the Cu film. In addition, it is possible to form the wiring section 104 using the method described in Embodiment 1.

Next, the process proceeds to as shown in FIG. 5B, wherein a ditch 107a and a through hole 107b are formed in the second insulation layer 106, for example, by a dry etching method.

Next, in the process shown in FIG. 6A, a Cu diffusion prevention film 107c is formed on the upper surface of the second insulation layer 106, the inner surface of the wall of the ditch 107a, the through hole 107b, and the exposed part of the wiring section 104. The Cu diffusion prevention film 107c in this case consists of, for example, a lamination of a Ta film and a TaN film, and can be formed by, e.g., sputtering, or alternatively, by the method of supplying the processing medium (i.e., the medium in the supercritical state in which the precursor is dissolved) using the film formation apparatus 10 as described in Embodiment 1. In this case, it is possible to form the Cu diffusion prevention film on the fine-pattern with satisfactory coverage. In this case, one of the following can serve as the precursor, namely, TaF₅, TaCl₅, TaBr₅, TaI₅, (C₅H₅)₂TaH₃, (C₅H₅)₂TaCl₃, PDMAT (Pentakis(dimethylamino)Tantalum, [(CH₃)₂N]₅Ta, PDEAT (Pentakis(diethylamino)Tantalum), [(C₂H₅)₂N]₅Ta, TBTDET (Ta(NC(CH₃)₃(N(C₂H₅)₂)₃), TAIMATA (a registered trademark, Ta(NC(CH₃)₂C₂H₅)(N(CH₃)₂)₃. Further, if, for example, CO₂ or NH₃ is used as the medium in the supercritical state, the Cu diffusion prevention film 107c consisting of Ta/TaN can be formed. Further, the Cu diffusion prevention film can be formed by the so-called ALD method.

Next, in the process shown in FIG. 6B, a wiring section 107 made of Cu is formed on the Cu diffusion prevention film 107c in the ditch 107a and the through hole 107b by the method described in Embodiment 1. In this case, since the processing medium is CO₂ in the supercritical state in which the precursor is dissolved, Cu film formation is carried out with satisfactory diffusion, and the wiring section 107 is formed in the through hole 107b and the ditch 107a including their bottoms and the sidewalls with satisfactory filling and coverage properties.

In this case of the present embodiment, the processing medium is supplied on the target substrate, the temperature of which is set at the first temperature that is less than the film formation minimum temperature (the lowest temperature at which film formation takes place) as described in the Embodiment 1; the precursor, which is substantially non-reacted, is fully provided into the through hole 104b and the ditches 104a. Then, the target substrate is heated from the first temperature to the second temperature that is greater than the film formation minimum temperature such that the film is formed filling up the through hole 104b and the ditches 104a on the target substrate.

For this reason, the film formation method according to the present invention, as compared with the conventional film formation method, is capable of forming a reliable wiring section to a miniaturized through hole and a ditch with improved filling and coverage properties while voids are prevented from occurring.

Further, after the process described above, one or more additional insulation layers can be formed, to each of which insulation layers a wiring section of Cu can be formed using the film formation method of the present invention.

Further, although the laminating film consisting of Ta/TaN is used as the Cu diffusion prevention film according to the present Embodiment, it is not limited to this, but various materials can serve the Cu diffusion prevention film, for example, a WN film, a W film, and a laminated film of Ti and TiN.

Further, the Cu diffusion prevention film may be served by a so-called self-organizing monomolecular film, which can be obtained by using, for example, 3-[2(trimethoxysilyl)ethyl]pyridine, and 2-(diphenylphosphor) ethyl triethoxysilane. Since the self-organizing monomolecular film can be made as thin as approximately one-molecule thick, the Cu diffusion prevention film is made thin, and is suitable for forming the miniaturized wiring. Further, the self-organizing monomolecular film can be formed by adsorbing a raw material in the liquid phase or in the gaseous phase on a target object such as an insulator layer; and the self-organizing monomolecular film or self assembled monolayers can also be formed by dissolving a material on a medium in the supercritical state as described in the present Embodiment for forming the Cu film.

Further, the first insulation layer 103 and the second insulation layer 106 may be made of various materials, for example, a silicon oxide film (SiO₂ film), a fluorine added silicon oxide film (SiOF film), and a SiCO(H) film.

### Embodiment 3

Further, the processing container to which the present invention is applicable is not limited to the processing container 30 as shown by FIGS. 2, 3A, and 3B, but other forms can be used and modifications are possible as described below.

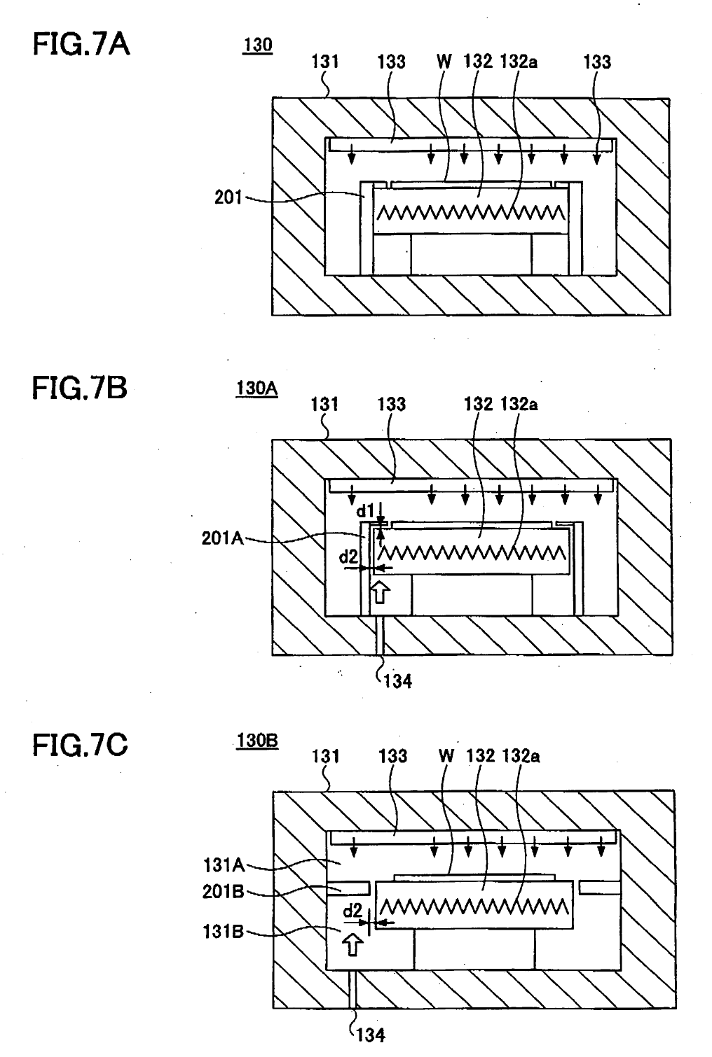

FIGS. 7A, 7B, and 7C show processing containers 130, 130A, and 130B, respectively, which are modifications of the processing container 30, and which can be used in the film formation apparatus 10 in place of the processing container 30.

The processing container 130 as shown in FIG. 7A includes an outer wall structure 131 that forms (delimits) a processing space. A holding stand 132 is arranged in the processing space for holding a target substrate W, and a heater 132a is arranged in the holding stand 132. Further, a supply section 133 for supplying a processing medium, etc., to the processing space is arranged in the processing space at a position countering the holding stand 132. The holding stand 132 and the supply section 133 correspond to the holding stand 32 and the supply section 33, respectively, of the processing container 30, and have the same functions, respectively. Although illustration is omitted in FIGS. 7A, 7B, and 7C, the processing containers 130, 130A, and 130B can use the line 14, the gate valve, the vertical-movement mechanism of the holding stand, etc. that are used by the processing container 30, and can be used to constitute the film-formation apparatus 10 for carrying out the same functions as in the case of the processing container 30. Further, in the drawings subsequent to FIG. 7A, the same reference marks are given to the same portions explained with reference to FIG. 7A, and the explanations thereof are not repeated.

The processing container 130 shown in FIG. 7A includes a shielding plate 201 for shielding the holding stand 132. The shielding plate 201 is installed such that it stands up from the bottom of the outer wall structure 131, and is formed such that the periphery section of the holding stand 132 is covered.

Here, the periphery section of the holding stand 132 is a section other than the portion occupied by the target substrate in the plane where the target substrate on the holding stand 132 is further supported by the sidewalls of the holding stand 132. In this way, film formation is prevented from being performed on the holding stand 132.

Further, the processing container 130 shown in FIG. 7A can be modified as a processing container 130A. FIG. 73 shows the outline of the processing container 130A which is the modification of the processing container 130. With reference to FIG. 7B, as in the case of the processing container 130, the processing container 130A includes a shielding plate 201A for covering the holding stand 132. The shielding plate 201A is installed so that it stands up from the bottom of the outer wall structure, and is formed so that the periphery section of the holding stand 132 may be covered, Here, the periphery section of the holding stand 132 is a section other than the portion occupied by the target substrate in the plane where the target substrate on the holding stand 132 is further supported by the sidewalls of the holding stand 132.

The shielding plate 201A is structured such that the medium in the supercritical state is supplied to a crevice between the holding stand 132 and the shielding plate 201A, wherein the medium in the supercritical state, for example, CO₂ is supplied from an inlet 134 arranged in the processing container 130A, and the crevice is purged by the medium in the supercritical state. In this way, the film formation in the crevice is effectively prevented from occurring. Further, the thickness of the crevice that is a distance d1 between the shielding plate 201A and the holding stand 132 is desirably 5 mm or less such that the film formation in the crevice is prevented from occurring.

Further, the processing container 130A shown in FIG. 7B can be modified as a processing container 1305. FIG. 7C shows the outline of the processing container 130B, which is the modification of the processing container 130A. With reference to FIG. 7C, the processing container 130B includes a shielding plate 201B that extends from the sidewall of the outer wall structure 131 toward the sidewall of the holding stand 132 such that the inside of the processing container 130B is divided into two parts, one part being a processing space 131A wherein the target substrate is present, and the other part being a space 131B that is on the opposite side of the processing space 131A. Then, from the inlet 134, the medium in the supercritical state, for example, CO₂ in the supercritical state, is supplied, and the space 131B is purged by the medium in the supercritical state. In this way, film formation in the space 131B is effectively prevented from occurring. Further, a distance d2 between the shielding plate 201B and the holding stand 132 is desirably set to 5 mm or less so that the film formation is prevented from occurring in the space 131B.

The target substrate often has a portion on which film formation is not desired. The film formation method according to the present invention can cope with this situation by arranging a shielding structure in the processing container such that film formation on the undesired portion of the target substrate is prevented from occurring.

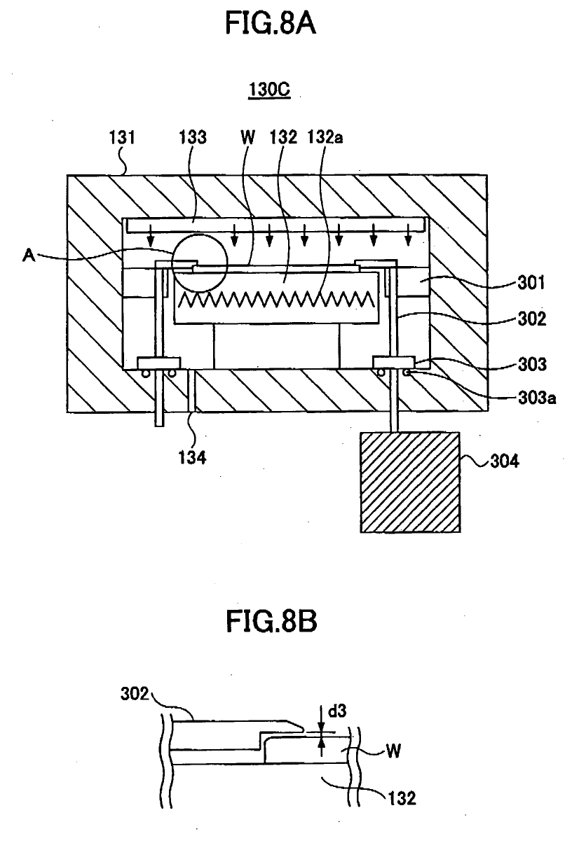

FIG. 8A shows the outline of a processing container 130C, which is another modification of the processing container 130. With reference to FIG. 8A, the processing container 130C includes a shielding structure 302 for shielding the periphery section of the target substrate. If, for example, a Cu film is formed near the periphery section including the sidewall and the edge portion called a bevel of the target substrate, the film has a greater tendency to be peeled off during a later process. To cope with this, the processing container 130C has the shielding structure 302 for covering the periphery section of the target substrate such that a film is prevented from forming on the periphery section, and exfoliation of the film during the later process is not a concern.

The shielding structure 302 includes a film formation prevention plate in the shape of a doughnut for covering the periphery section of the target substrate, and two or more supporting rods in the shape of a cylindrical pillar for supporting the film formation prevention plate. The supporting rods are inserted in holes formed on a supporting rod maintenance plate 301, the supporting rods extending in a direction from the inner surface of the wall of the outer wall structure 131 to the holding stand 132. The supporting rods penetrate the bottom of the outer wall structure 131 through flanges 303 that are sealed by seal sections 303a, and are connected to a driving unit 304.

The driving unit 304 vertically drives the shielding structure 301, and the film formation prevention plate of the shielding structure 301 is movable in directions approaching and departing from the target substrate. For example, the film formation prevention plate moves in the direction approaching the target substrate (upward) when the target substrate is carried in and out; and moves in the direction departing from the target substrate (downward) after the target substrate is placed on the holding stand, and is set at a predetermined position.

Further, the processing container 130C is structured such that the medium in the supercritical state is introduced into the crevice between the film formation prevention plate and the target substrate from the inlet 134 arranged on the processing container 130C. The medium, for example, CO₂ in the supercritical state is supplied, and the crevice is purged by the medium in the supercritical state. In this way, the film formation on the crevice is effectively prevented from occurring.

FIG. 8B is an enlargement of a portion indicated by “A” in FIG. 8A, i.e., an enlargement of the target substrate W and the shielding structure 301. With reference to FIG. 8B, the film formation prevention plate of the shielding structure 301 has a projecting section for covering the periphery section of the target substrate W. Here, a distance d3 between the film formation prevention plate and the holding stand 132 is desirably 1 mm or less such that film formation to the target substrate is prevented from occurring.

As described above, the film formation apparatus for carrying out the film formation method of the present invention can be varied and modified in various ways.

Further, the present invention is not limited to these embodiments, but variations and modifications may be made without departing from the scope of the present invention.

### AVAILABILITY ON INDUSTRY

The present invention offers a film formation method of forming a fine-pattern using a medium in the supercritical state, the method realizing sufficient filling and coverage properties greater than conventional methods, and realizing film formation on still more highly fine-patterns.

The present application is based on Japanese Priority Application No. 2004-304536 filed on Oct. 19, 2004 with the Japanese Patent Office, the entire contents of which are hereby incorporated by reference.

What is claimed is:

1. A film formation method of forming a film by supplying a processing medium on a target substrate, which processing medium is in a supercritical state and in which a precursor is dissolved, comprising:
a first process of setting the target substrate at a first temperature that is less than a film formation minimum temperature, which film formation minimum temperature is the lowest temperature at which film formation occurs, and supplying the processing medium on the target substrate; and
a second process of forming the film on the target substrate by raising the temperature of the target substrate from the first temperature to a second temperature that is greater than the film formation minimum temperature.

2. The film formation method as claimed in claim 1, wherein the first temperature is lower than the second temperature by greater than 50° C. and less than 300° C.

3. The film formation method as claimed in claim 1, wherein the first temperature is lower than the film formation minimum temperature by greater than 10° C. and less than 100° C.

4. The film formation method as claimed in claim 1, wherein the precursor is one of Cu(hfac)₂, Cu(acac)₂, Cu(dpm)₂, Cu(dibm)₂, Cu(ibpm)₂, Cu(hfac)TMVS, and Cu(hfac)COD.

5. The film formation method as claimed in claim 4, wherein the first temperature is between 100° C. and 250° C.

6. The film formation method as claimed in claim 4, wherein the second temperature is between 200° C. and 400° C.

7. The film formation method as claimed in claim 1, wherein the film is formed such that a pattern formed on the target substrate is filled.

8. The film formation method as claimed in claim 7, wherein the pattern is formed on an insulation layer that is formed on the target substrate.

9. The film formation method as claimed in claim 1, wherein a reducing agent of the precursor is added to the processing medium.

10. The film formation method as claimed in claim 1, wherein the medium in the supercritical state is CO₂.

11. The film formation method as claimed in claim 1, wherein
the first process and the second process are carried out in a processing container that has a holding stand for holding the target substrate inside the processing container,
the processing medium is supplied to the interior of the processing container, and
the temperature of the target substrate is raised by a heater prepared in the holding stand.

12. The film formation method as claimed in claim 11, wherein inert gas is supplied to the processing container when carrying the target substrate into and out from the processing container.

13. The film formation method as claimed in claim 11, wherein the processing container is connected to a substrate conveyance chamber that is capable of connecting two or more of the processing containers.

14. The film formation method as claimed in claim 13, wherein the processing container and another processing container are connected to the substrate conveyance chamber.

15. The film formation method as claimed in claim 11, wherein the processing container includes a shielding plate for shielding the holding stand.

16. The film formation method as claimed in claim 15, wherein the medium in the supercritical state is provided in a crevice between the shielding plate and the holding stand.

17. The film formation method as claimed in claim 11, wherein the processing container includes a film formation prevention plate for covering a periphery section of the target substrate that is held by the holding stand.

18. The film formation method as claimed in claim 17, wherein the film formation prevention plate is movable in directions approaching and departing from the target substrate.

19. The film formation method as claimed in claim 17, wherein the film formation prevention plate has a projecting section for covering the periphery section of the target substrate.

20. The film formation method as claimed in claim 17, wherein the medium in the supercritical state is supplied to a crevice between the film formation prevention plate and the holding stand.

21. A storage unit for storing a computer-executable program for a computer to perform the film formation method as claimed in claim 1.
